(19) United States
(12) Patent Application Publication
(10) Pub. No.: US 2015/0331447 A1
(43) Pub. Date: Nov. 19, 2015

(54) SUBSTRATE DEVICE COMPRISING A REINFORCING MEMBER

(71) Applicant: Kabushiki Kaisha Toshiba, Tokyo (JP)

(72) Inventor: Kenji Hasegawa, Hamura Tokyo (JP)

(21) Appl. No.: 14/637,202

(22) Filed: Mar. 3, 2015

Related U.S. Application Data
(60) Provisional application No. 61/993,584, filed on May 15, 2014.

(51) Int. Cl. G06F 1/16; H05K 1/02

(52) U.S. Cl. CPC G06F 1/163; H05K 1/0281

(57) ABSTRACT

According to one embodiment, a substrate device is mounted on a wearable device that is worn, curved. The substrate device is provided with a long flexible printed circuit substrate comprising, an electronic component mounted on the surface of the flexible printed circuit substrate, a connector to electrically connect the electronic component to the flexible printed circuit substrate, and at least one reinforcing member mounted on the surface of the flexible printed circuit substrate near the connector.

### CROSS-REFERENCE TO RELATED APPLICATIONS

This application claims the benefit of U.S. Provisional Application No. 61/993,584, filed May 15, 2014, the entire contents of which are incorporated herein by reference.

### FIELD

Embodiments described herein relate generally to a substrate device comprising a reinforcing member.

### BACKGROUND

Wearable devices have recently been increasingly available in the market. In accordance with this, there is a demand for downsizing and thinning of the wearable devices. In general, since wearable devices of a wristband type are worn on a body, it is necessary to curve the devices. Therefore, it is effective to use a flexible printed circuit board (FPC) as a board contained in the wearable devices. In this case, however, since the device will be curved when it is worn, stress may well occur in the connection between the FPC and the components thereon. In the prior art, a reinforcing plate is attached to the reverse surface of the FPC to reduce the stress on the connection. When the reinforcing plate is attached, the entire board will inevitably be thickened. Further, it is possible to reinforce the mounted components by coating them with an underlying film or an adhesive. This, however, increases the number of process steps, and hence increases the manufacturing cost of the wearable device.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective view showing an example of a wearable device on which a substrate device is mounted according to a first embodiment;

FIG. 2 is a perspective view of the substrate device;

FIG. 3 is a block diagram showing the substrate device;

FIG. 4A is a side view showing part of the substrate device;

FIG. 4B is a top plan view showing part of the substrate device;

FIG. 4C is a side view showing part of the substrate device in a curved state;

FIG. 5A is a side view showing part of a substrate device according to a first modification;

FIG. 5B is a top plan view showing part of the substrate device of the first modification;

FIG. 6 is a top plan view showing part of a substrate device according to a second modification;

FIG. 7 is a top plan view showing part of a substrate device according to the second modification;

FIG. 8 is a top plan view showing part of the substrate device according to the second modification;

FIG. 9 is a top plan view showing part of a substrate device according to a third modification;

FIG. 10A is a top plan view showing a substrate device according to a second embodiment;

FIG. 10B is a cross-sectional view showing the substrate device according to a second embodiment;

FIG. 10C is a side view showing the substrate device of the second embodiment;

FIG. 11A is a top plan view showing part of a substrate device according to a first modification of the second embodiment; and

FIG. 11B is a side view showing part of the substrate device according to the first modification of the second embodiment.

### DETAILED DESCRIPTION

Various embodiments will be described hereinafter with reference to the accompanying drawings.

In general, according to one embodiment, a substrate device is mounted on a wearable device that is worn, curved. The substrate device is provided with a long flexible printed circuit substrate comprising wiring, an electronic component mounted on the surface of the flexible printed circuit substrate, a connection to electrically connect the electronic component to the flexible printed circuit substrate, and at least one reinforcing member mounted on the surface of the flexible printed circuit substrate near the connection.

Embodiments will be described with reference to the accompanying figures.

### First Embodiment

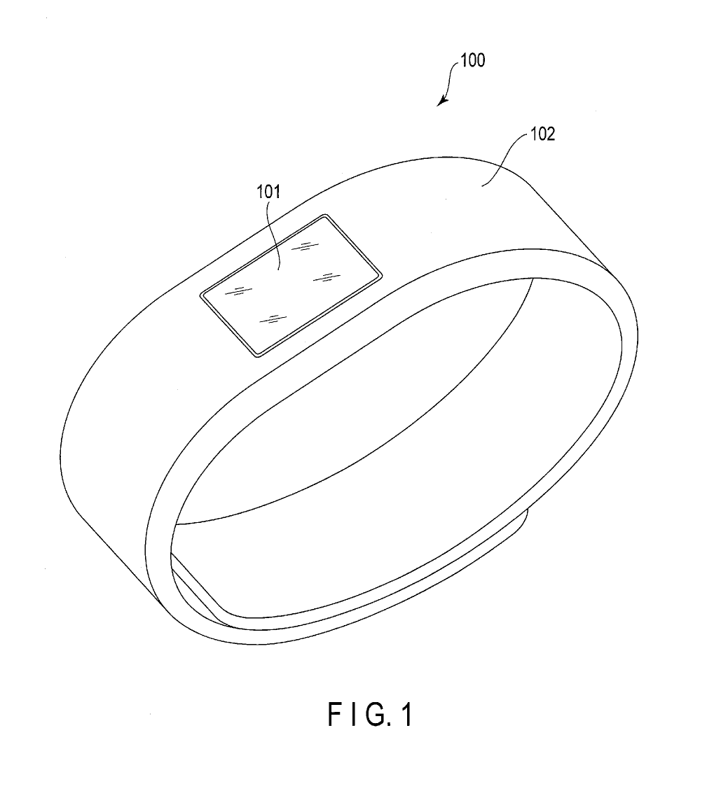

FIG. 1 is a perspective view showing an example of a wearable device 100 according to a first embodiment. The wearable device 100 comprises a display unit 101 and a cover member 102 covering the entire device. The wearable device 100 further comprises a substrate device 1 covered with the cover member 102. The substrate device 1 will be described later in detail. The wearable device 100 has an elongated shape of a predetermined width. For instance, the wearable device 100 is of a wristband type and is configured to be worn on a wrist of a user. The wearable device 100 can acquire biological data of the user when it is worn on them. The wearable device 100 can also transmit the acquired biological data to an external device and obtain data from the external device.

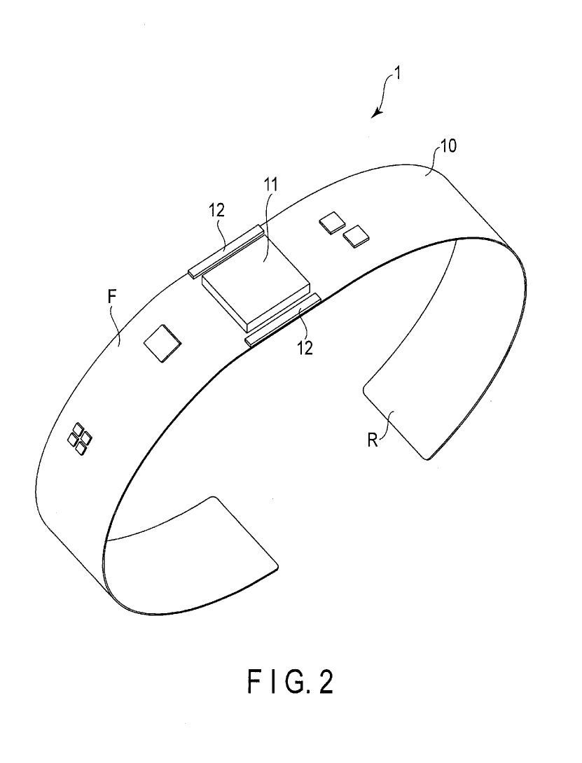

FIG. 2 is a perspective view of the substrate device 1 installed in the wearable device 100. The substrate device 1 according to the first embodiment mainly comprises a flexible printed circuit board (FPC) 10, an electronic component unit 11 and reinforcing members 12. The FPC 10 of the substrate device 1 has an obverse F and a reverse R. In the description below, if something is on the obverse F of the FPC 10, this may be expressed simply as “something on the FPC 10.” In the substrate device 1, the electronic component unit 11 includes a plurality of electronic components 11 mounted on the flexible FPC 10. The substrate device 1 is provided along the entire length of the wearable device 100. Namely, the wearable device 100 has flexibility over the entire length. Accordingly, when the wearable device 100 is wound on, for example, a wrist like a wristband, it will be fitted.

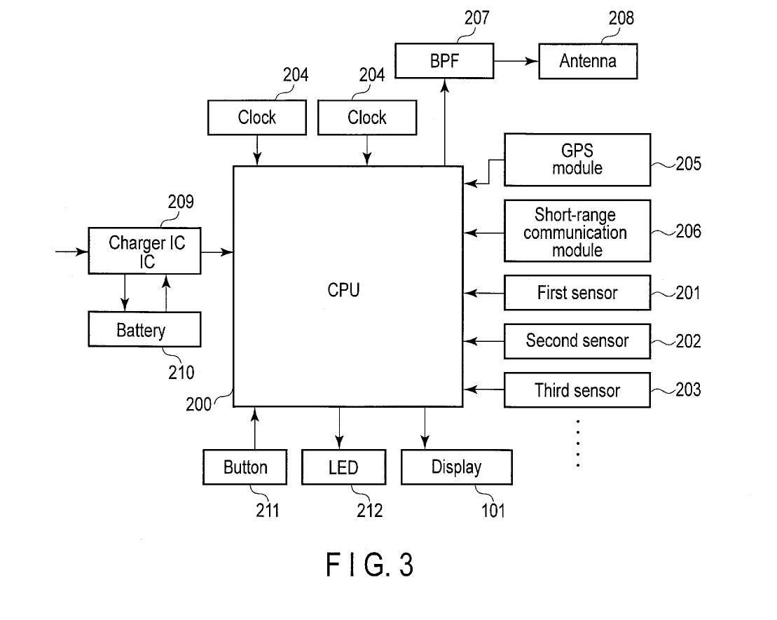

FIG. 3 is a block diagram showing the substrate device 1. An example of the electronic component unit 11 mounted on the substrate device 1 will now be described.

As the electronic components 11, the substrate device 1 comprises a CPU 200, a first sensor 201, a second sensor 202, a third sensor 203 and a clock 204. The substrate device 1 further comprises a GPS module 205, a short-range communication module 206, a band-pass filter (BPF) 207, an antenna 208, a charger IC 209, a battery 210, a button 211 and an LED 212.

The CPU 200 is a main controller configured to control the operations of the wearable device 100. The CPU 200 has, for example, an accelerator, a magnetometer and a gyroscope. For instance, the CPU 200 causes the display unit 101 to display, for example, acquired information.

The first to third sensors 201, 202 and 203 are used to detect biological data. For instance, the first sensor 201 is an audio sensor, the second sensor 202 is a pressure sensor, and the third sensor is a temperature sensor. The first sensor 201 senses biological sounds, such as cardiac sound, pulse beats. The second sensor 202 senses, for example, blood pressure. The third sensor 203 senses body temperatures. The thus obtained data is transmitted to the CPU 200, where it is analyzed and processed.

The clock 204 is, for example, a real-time clock (RTC). Even when power to the wearable device 100 is interrupted, the clock 204 continues to operate. The frequency of the clock 204 is sent to the CPU 200.

The GPS module 205 is used to send and receive signals to and from a satellite communication system to detect the position of the user through the processing of the CPU 200.

The short-range communication module 206 is, for example, Bluetooth (trademark), Wi-Fi, etc. The short-range communication module 206 realizes data communication between the wearable device 100 and the external device. The communication of data by the short-range communication module is controlled and processed by the CPU 200. For instance, biological data acquired by the wearable device 100 is displayed on, for example, the display unit 101.

The BPF 207 is a filter circuit configured to pass only frequencies of a necessary range included in the signals from, for example, the CPU 200, and not to pass the other frequencies.

The antenna 208 is used to transmit and receive data to and from the external device under the control of the CPU 200.

The charger IC 209 is configured to acquire electricity from an external power supply to charge the battery 210. Thus, the battery 210 receives electricity via the charger IC 209.

The battery 210 is a power supply for the wearable device 100, and supplies power to, for example, the CPU 200 via the charge IC.

The button 211 is used to operate the wearable device 100 and to determine and switch data displayed on the display unit 101. For instance, upon receiving a signal from the button 211, the CPU 200 switches display on the display unit 101.

The LED 212 emits light when power is applied. For instance, the LED 212 may be used as electrical spectaculars for the wearable device 100, or as an alarming device for giving an alarm to the user by emitting colored light. The light emission of the LED 212 is controlled by the CPU 200.

The display unit 101 may not be employed. In this case, an emission section incorporated in, for example, the LED may be provided at the same position as the display unit 101.

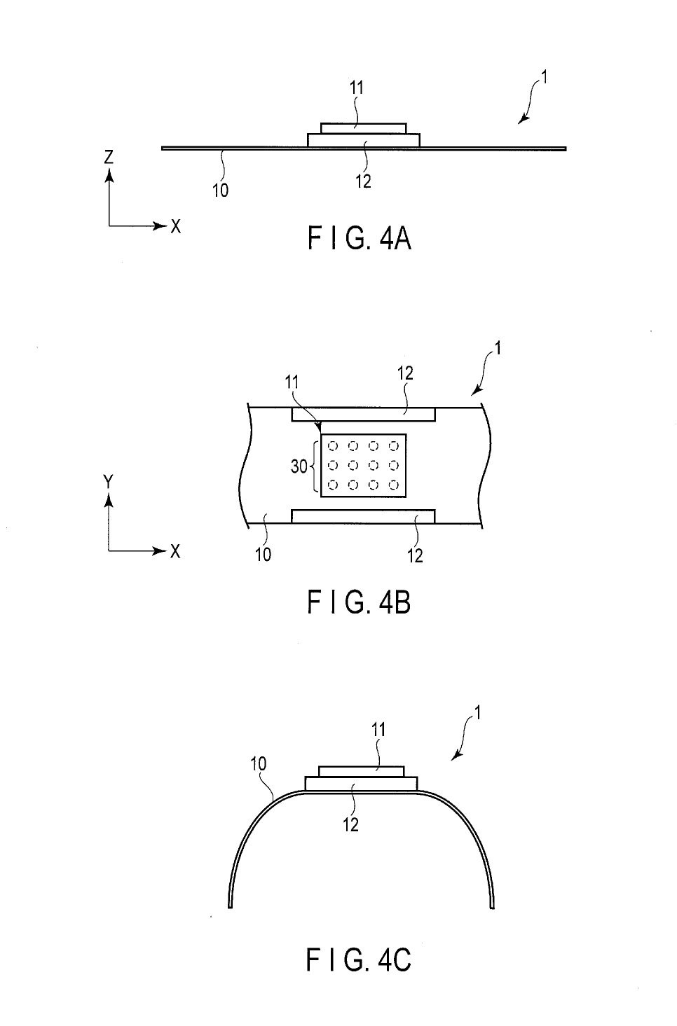

FIG. 4A is a side view showing part of the substrate device 1. FIG. 4B is a top plan view showing part of the substrate device 1. FIG. 4C is a side view showing part of the substrate device 1 in a curved state. In FIG. 4A, the Z-axis direction will hereinafter be referred to as the upward direction (upward), the direction opposite to the upward direction be referred to as the downward direction (downward), the X-axis direction be referred to as the rightward direction (rightward), the direction opposite to the rightward direction be referred to as the leftward direction (leftward), the Y-axis direction be referred to as the rearward direction (rearward), and the direction opposite to the rearward direction be referred to as the frontward direction (frontward). Further, the length of the member along the Y-axis will be referred to as the width, and the length along the Z-axis be referred to as the thickness (or height).

The structure of the substrate device 1 will be described.

As shown in FIGS. 2, 4A and 4B, the substrate device 1 is a long plate-like member. The FPC 10 is insulated over the entire surface. The FPC 10 has a laminated structure in which insulating and conductive layers are alternately stacked. In the first embodiment, the FPC 10 comprises insulating layers, a patterned wiring layer obtained by patterning a conductive layer on the insulating layer, connection pads, and a protective layer (insulating layer or solder resist). The insulating layers are, for example, resin films (formed of polyimide, solder resist, etc.). The connection pads in the FPC 10 are used for mounting the electronic components 11 and the reinforcing members 12. Each connection pad may be formed of a through hole, or a metal terminal formed by removing part of an insulator. Part of the connection pads are electrically connected to the patterned wiring layer.

As mentioned above, the electronic component unit 11 comprises a plurality of electronic components. The electronic components 11 include respective connection elements (connection)30 for connecting the components to the FPC 10. The electronic component unit 11 is formed of, for example, a semiconductor element of a ball grid array (BGA) structure. In the description below, the electronic component unit 11 will be referred to as a BGA 11, for convenience sake. The BGA 11 is formed rectangular and extends along the length of the FPC 10. The BGA 11 is placed on the obverse F of the FPC 10 in the vicinity of the center of the width of the FPC 10 and the center (the center of the FPC 10) of the length of the FPC 10 along the X-axis. In this case, the BGA 11 is positioned, for example, such that its long sides are parallel to the X-axis and its short sides are parallel to the Y-axis. Further, the center of the BGA 11 is positioned to coincide with the center of the FPC 10. The BGA 11 may be formed to, for example, a square with one side of 1 mm. Further, the BGA 11 may be formed to a square with one side of 1 mm to 3 mm. The BGA 11 is not limited to a square with one side of 1 mm to 3 mm, but may be formed to other sizes and/or other shapes. The electronic component 11 may be a semiconductor element other than BGA.

The connection 30 of the FPC 10 mechanically and electrically connects the BGA 11 to the FPC 10. The connection 30 is formed of solder or an adhesive. In this embodiment, the connection 30 has a plurality of solder balls. The solder balls are regularly arranged. For instance, the solder balls are arranged at regular intervals like a grid so that they are symmetrical with respect to substantially the center of the width of the FPC 10. Each solder ball is soldered to a connection terminal of the BGA 11 and a connection pad of the FPC 10.

For example, in a manufacturing process for the substrate device 1, the BGA 11 is placed on the connection pads of the flat FPC 10. After that, the connection pads of the FPC 10 are connected to the connection 30 (solder balls) by reflow, whereby the BGA 11 is mechanically and electrically connected to the FPC 10.

Each reinforcing member 12 is formed like a long, thin and flat plate having long and short sides. As shown in FIGS. 2, 4A and 4B, each reinforcing member 12 is formed longer at least than that of the sides of the connection 30, and thinner than the thickness (height from the surface F) of the BGA 11. Each reinforcing member 12 is formed of a metal, such as SUS, aluminum, etc. The reinforcing members 12 are arranged such that their longitudinal axes are parallel to the X-axis. Further, the reinforcing members 12 are mounted, by soldering, onto connection pads provided at the rearward and frontward ends (opposite side edges) of the surface F of the FPC 10. Namely, the reinforcing members 12 are provided on the same surface as the electronic components 11. The reinforcing members 12 are positioned such that their central portions along the X-axis are aligned with the central portion of the electronic component unit 11 along the X-axis. In other words, the electronic component unit 11 and the reinforcing members 12 are mounted so that the central portions of the members along the Y-axis are aligned with the central portion of the electronic component unit 11 along the Y-axis. The reinforcing members 12 may be provided along the opposite side edges of the BGA 11 of, preferably, 1 mm or more, and along a plurality of BGAs 11. For instance, if two BGAs 11 of a 1 mm square are provided adjacent to each other, respective reinforcing members 12 are mounted at the opposite side edges of the two BGAs 11. In this case, the reinforcing members 12 each have a length greater than the total length of the two BGAs 11, and are arranged in parallel with the opposite side edges of the FPC 10. In the manufacturing process, the reinforcing members 12 may be soldered by reflow to the FPC simultaneously with the BGA 11.

The reinforcing members 12 are not limited to long, thin and flat plates, but may be formed like round bars. Further, the reinforcing members 12 may be mounted on the FPC 10 by an adhesive other than solder. In addition, the BGA 11 may be mounted in any attitude on the FPC 10 between two reinforcing members 12 parallel to each other.

In the first embodiment, when the FPC 10 is curved as shown in FIG. 4C, the reinforcing members 12 maintain their vicinities substantially flat. Namely, curving of the vicinity of the connection 30 of the electronic component unit 11 is suppressed. Accordingly, stress occurring at the BGA 11 and the connection 30 is reduced. Further, provision of the reinforcing members 12 in the same plane as the BGA 11 can minimize the thickness of the resultant substrate device. Moreover, since the reinforcing members 12 are formed thinner than the BGA 11, the substrate device 1 can be formed thin. In addition, since the reinforcing members 12 are fixed by soldering on the FPC 10, the number of steps for manufacturing the substrate device 1 can be reduced to thereby suppress the manufacturing cost.

Some modifications of the first embodiment will be described with reference to the drawings corresponding thereto. Since substrate devices 1 according to the modifications have substantially the same structure as the substrate device 1 of the first embodiment, elements similar to those of the substrate 1 of the first embodiment are denoted by corresponding reference numbers, and no detailed description will be given thereof.

### First Modification

A first modification will firstly be described. The substrate device 1 of the first modification differs from the substrate device 1 of the first embodiment in the shape and arrangement of the reinforcing members 12.

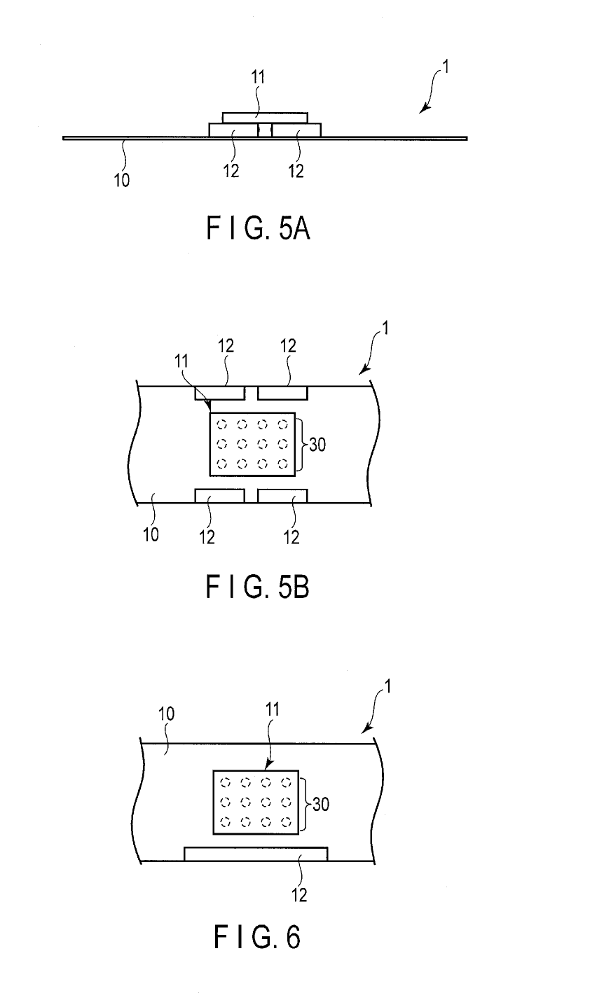

FIG. 5A is a side view showing part of a substrate device according to the first modification. FIG. 5B is a top plan view showing part of the substrate device of the first modification.

In the first modification, a plurality of reinforcing members 12 are arranged linearly in parallel with the X-axis along each of the rearward and frontward ends (opposite side edges) of the FPC 10. The reinforcing members 12 arranged along each of the opposite side edges are separate from each other with a predetermined space therebetween. The reinforcing members 12 surround the BGA 11. Namely, the four reinforcing members 12 provided along the opposite side edges protrude from the ends of the BGA 11 along the X-axis. However, the length of each reinforcing member 12 may be shorter than the length of the BGA 11 along the X-axis. For instance, the length of each reinforcing member 12 may be set to ½ the length of the BGA 11. Further, the height (thickness) of each reinforcing member 12 is set lower than that of the electronic component unit 11 on the FPC 10.

In the first modification, when the FPC 10 is curved, the reinforcing members 12 maintain their vicinities substantially flat. Namely, curving of the vicinity of the connection 30 of the electronic component unit 11 can be suppressed.

In the first modification, since a larger number of reinforcing members 12 than in the first embodiment are used, they can be effectively arranged. Further, in the first modification, the reinforcing members 12 can be arranged at a higher degree of freedom than in the first embodiment.

It is not always necessary to provide the same number of reinforcing members 12 along the opposite side edges of the FPC 10. Further, the reinforcing members 12 mounted along the opposite side edges may not face each other. For instance, one reinforcing member 12 may be mounted along one of the edges, and two reinforcing members 12 be mounted along the other edge.

### Second Modification

A second modification will be described. A substrate device according to the second modification differs from the first embodiment in reinforcing member arrangement and material.

FIG. 6 is a top plan view showing part of the substrate device 1 according to the second modification.

In the second modification, a reinforcing member 12 is provided along one of the opposite side edges of the FPC 10 between which the BGA 11 is provided along the Y-axis. For instance, only one of the two reinforcing members 12 in the first embodiment is employed in this modification. Accordingly, at least the length of the reinforcing member 12 is greater than that of the connection 30, e.g., than the length of the BGA 11 along the X-axis.

In the second modification, when the FPC 10 is curved, the reinforcing member 12 maintains its vicinity substantially flat. Namely, curving of the vicinity of the connection 30 of the electronic component unit 11 can be suppressed. Since thus, the reinforcing member 12 is secured to one of the rearward and frontward ends (opposite side edges) of the FPC 10, the number of components constituting the reinforcing member 12 can be reduced, compared to the above-described embodiment and modification.

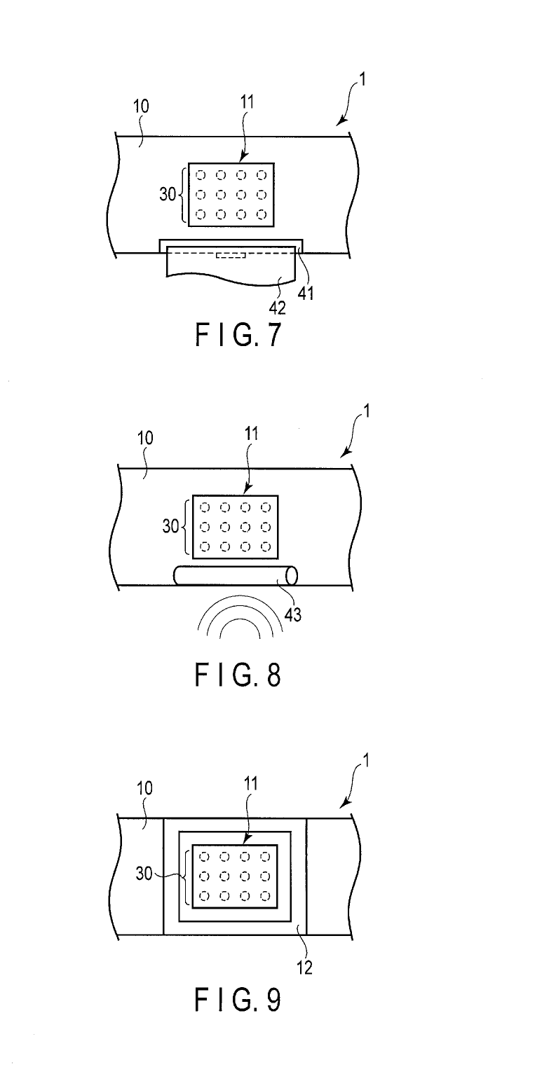

The second modification may employ a connector 41 as the reinforcing member 12 as shown in FIG. 7. The connector 41 is a terminal that is connectable to an external device via, for example, a cable 42, to transmit and receive data to and from the same. Further, the second modification may employ as the reinforcing member 12 a communication device (communication member) 43 including a short-range communication module 206, as is shown in FIG. 8. The communication device 42 is configured to transmit and receive radio waves to and from an external device. The communication device 43 is, for example, a Bluetooth (trademark) module. The use of the connector 41 or the communication device 42 as the reinforcing member 12 can dispense with provision of another reinforcing member 12.

### Third Modification

A third modification will be described. A substrate device 1 according to the third modification differs from the above-described substrate devices 1 in the shape or arrangement of the reinforcing member(s) 12.

FIG. 9 is a top plan view showing part of the substrate device 1 according to the third modification.

In the third modification, the reinforcing member 12 is formed like a rectangular frame to surround the BGA 11. The frame-shaped reinforcing member 12 is positioned such that the center of the area inside the frame coincides with the center of the BGA 11 along the X-axis. This structure maintains the vicinity of the reinforcing member 12 substantially flat when the FPC 10 is curved. Namely, curving of the vicinity of the connection 30 of the electronic component unit 11 is suppressed. In addition, the reinforcing member 12 serves to suppress twisting about the X-axis, as well as the curving of the FPC 10 along the X-axis.

A substrate device according to another embodiment will be described. In this embodiment, elements similar to those of the first embodiment are denoted by corresponding reference numbers, and no detailed description will be given thereof.

### Second Embodiment

A second embodiment will be described. A substrate device according to the second embodiment differs in that each reinforcing member a clip and a shield plate.

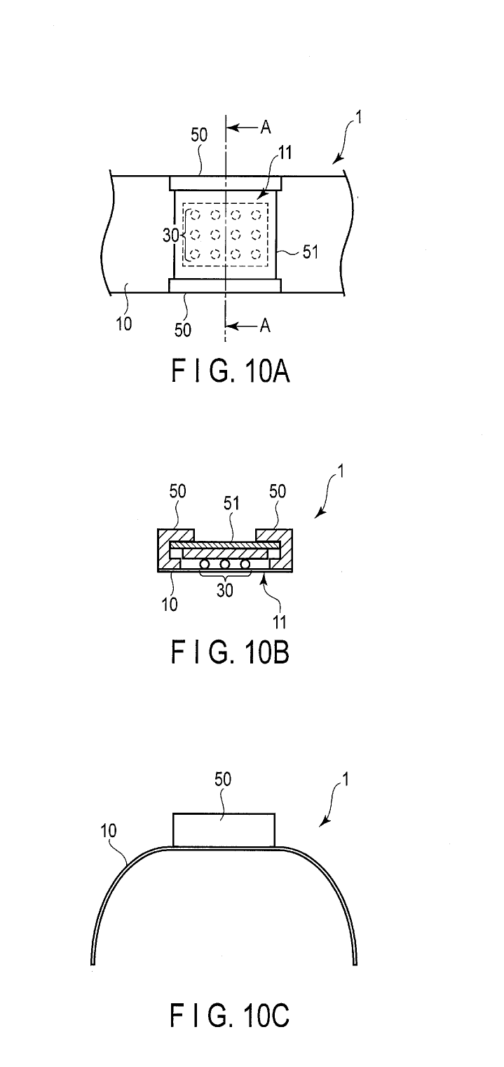

FIG. 10A is a top plan view showing the substrate device 1 according to the second embodiment. FIG. 10B is a cross-sectional view of the substrate device, taken along line A-A of FIG. 10A. As shown, the substrate device 1 comprises a FPC 10, a BGA 11 including a connection 30, clips (fixing members) 50 and a shield plate 51.

As shown in FIG. 10A, the clips 50, which extend along the X-axis, are mounted on the FPC 10 along the opposite side edges of the FPC 10. The clips 50 are arranged parallel to each other. The clips 50 are used to secure the shield plate 51. The clips 50 are formed of, for example, a metal. The shield plate is used to protect the BGA 11 from noise waves. The shield plate 51 is formed to a size with which the shield plate can be held between the opposing clips 50. The shield plate 51 is positioned on the BGA 11. The shield plate 51 is formed of, for example, a metal.

As shown in FIG. 10B, the clips 50 clip the shield plate 51 to secure the BGA 11. The clips 50 are formed to have a U-shaped cross section. The shield plate 51 is inserted in the recesses of the clips 50. The two clips 50 are arranged such that the recesses oppose each other. The bottoms of the clips 50 are connected to the connection pads of the FPC 10 by soldering. Alternatively, the clips 50 may be attached to the FPC 10 by another adhesive.

FIG. 10C is a side view showing a state in which the substrate device 1 of the second embodiment is curved. When the FPC 10 is curved, the clips 50 and the shield plate 51 maintain the vicinity of the BGA 11 substantially flat. Namely, curving of the vicinity of the connection 30 of the BGA 11 is suppressed.

In the second embodiment, the clips 50 and the shield plate 51 increase the strength of the FPC 10 against curving when the FPC is curved, compared to the above-described embodiment and modifications. Namely, the force exerted on the connection 30 can be reduced compared to the above-described embodiment and modifications. Further, the shield plate 51 protects the BGA 11 from, for example, noise waves.

### First Modification

A first modification of the second embodiment will be described. A substrate device 1 according to the first modification differs in shape from the above-described substrate device 1 and the clips.

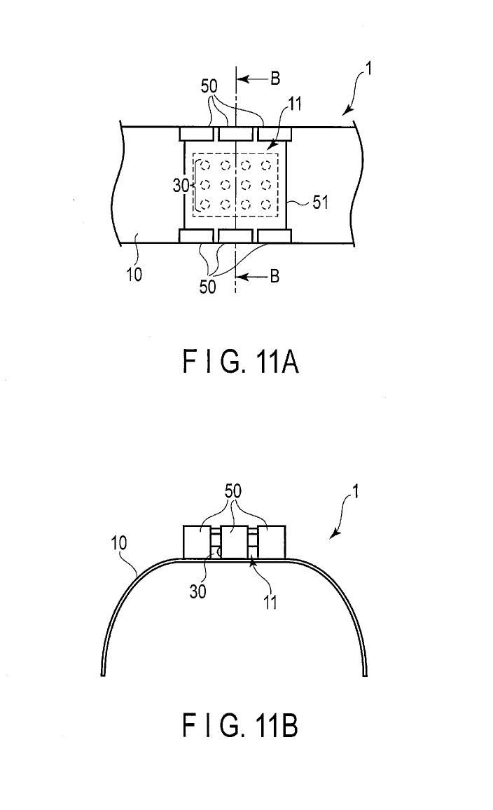

FIG. 11A is a top plan view showing part of the substrate device 1 according to the first modification. The cross section taken along line B-B of FIG. 11A is equivalent to that of the substrate device of FIG. 10B. The substrate device 1 of the fourth modification comprises a plurality of clips and a shield plate 51.

As shown in FIG. 11A, a plurality of clips 50 are arranged linearly along the X-axis at each of the opposite side edges of the FPC 10. At each side edge, the clips are arranged at regular intervals to surround the BGA 11.

The shield plate 51 is formed to a size with which it falls within the range surrounded by the clips 60.

FIG. 11B is a side view showing part of the substrate device 1 according to the first modification. In this modification, when the FPC 10 is curved, the clips 50 and the shield plate 61 maintain the vicinity of the BGA 11 substantially fiat. Namely, curving of the vicinity of the connection 30 of the electronic component unit 11 is suppressed. Since the clips 50 can clip the shield plate 51, the BGA 11 can be further rigidly secured than in the second embodiment. Further, the use of a plurality of clips 50 at each side edge enables the clips 50 to be more effectively arranged.

As described above, in the first and second embodiments, when the FPC 10 is curved, the reinforcing member(s) maintains the BGA 11 and the connection 30 in a flat state. Accordingly, the stress occurring in the BGA 11 and the connection 30 is reduced. Further, by providing the FPC with the reinforcing member(s) 12, the shield plates 50, 60, etc., on the same plane, the thickness of the resultant substrate device 1 can be suppressed. Yet further, since the reinforcing members 12 are formed thinner than the thickness of the BGA 11, the substrate device 1 can be made thinner. Also, since the reinforcing members 12 are soldered to the FPC 10, the number of process steps for manufacturing the substrate device 1 can be suppressed, whereby the manufacturing cost can be suppressed.

The BGA 11 does not have to be set parallel to the opposite side edges of the FPC 10. The attitude of the BGA 11 is not limited. It is sufficient if the BGA 11 is received within a range on the FPC 10, within which the reinforcing members 12 are mounted.

Although in the above-described embodiments and modifications, the BGA 11, the reinforcing members 12, the clips 50 and the shield plate 51 are mounted on the obverse F of the FPC 10, they may be mounted on the reverse surface R.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A substrate device mounted on a flexible wearable device comprising:
a long flexible printed circuit substrate comprising;
an electronic component mounted on a surface of the flexible printed circuit substrate;
a connector to electrically connect the electronic component to the flexible printed circuit substrate; and
at least one reinforcing member mounted on the surface of the flexible printed circuit substrate near the connector.

2. The substrate device of claim 1, the flexible printed circuit substrate having a width and a length exceeding the width, wherein the reinforcing member is not shorter than the connector in the length direction.

3. The substrate device of claim 2, wherein the reinforcing member is not thicker than the electronic component.

4. The substrate device of claim 2, wherein the reinforcing member is mounted on the surface along a side edge of the flexible printed circuit substrate.

5. The substrate device of claim 1, wherein the reinforcing member is soldered on the surface.

6. The substrate device of claim 1, wherein
the reinforcing member comprises a shield member protecting the electronic component from above, and a fixing member fixing around a side of the electronic component and a side of the shield member; and
the fixing member is soldered on the surface.

7. The substrate device of claim 4, wherein the reinforcing member also serves as a communication member configured to receive and transmit information.

8. A substrate device comprising:
a long flexible printed circuit substrate comprising;
an electronic component mounted on a surface of the flexible printed circuit substrate;
a connector to electrically connect the electronic component to the flexible printed circuit substrate; and
at least one reinforcing member mounted on the surface of the flexible printed circuit substrate near the connection.

9. The substrate device of claim 8, the flexible printed circuit substrate having a width and a length exceeding the width, wherein the reinforcing member is not shorter than the connector in the length direction.

10. The substrate device of claim 9, wherein the reinforcing member is not thicker than the electronic component.

11. The substrate device of claim 9, wherein the reinforcing member is mounted on the surface along a side edge of the flexible printed circuit substrate.

12. The substrate device of claim 8, wherein the reinforcing member is soldered on the surface.

13. The substrate device of claim 8, wherein
the reinforcing member comprises a shield member protecting the electronic component from above, and a fixing member fixing around a side of the electronic component and a side of the shield member; and
the fixing member is soldered on the surface.

14. The substrate device of claim 11, wherein the reinforcing member also serves as a communication member to receive and transmit information.
